(19) United States
(12) Patent Application Publication
(10) Pub. No.: US 2007/0085184 A1
(43) Pub. Date: Apr. 19, 2007

(54) STACKED DIE PACKAGING SYSTEM

(75) Inventors: Hyeog Chan Kwon, Seoul (KR); Hee Bong Lee, Kyoungki-Do (KR)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/163,313

(22) Filed: Oct. 13, 2005

(51) Int. Cl. H01L 23/02; H01L 21/00

(52) U.S. Cl. 257/686; 438/109; 257/E23.085

(57) ABSTRACT

A substrate is provided. A first die is placed on the substrate. A film spacer is attached to the first die and a second die is placed on the film spacer. The substrate, the first die, the film spacer, and the second die are encapsulated in an encapsulant.

### CROSS-REFERENCE TO RELATED APPLICATION(S)

The present application contains subject matter related to previously filed U.S. application Ser. No. 10/976,601 filed Oct. 26, 2004, which claims priority from U.S. Provisional Application No. 60/549,174, filed Mar. 2, 2004. The related application was published on Sep. 22, 2005, under publication number US 2005-0208701 A1. The subject matter thereof is hereby incorporated by reference thereto.

### TECHNICAL FIELD

The present invention relates generally to integrated circuits, and more particularly to package structures for integrated circuits.

### BACKGROUND ART

The computer industry continually strives toward higher performance, lower cost, increased miniaturization of components, and greater packaging density of integrated circuits (“IC's”). As new generations of IC products are released, their functionality increases while the number of components needed to produce them decreases.

Semiconductor devices are constructed from a silicon or gallium arsenide wafer through a process that comprises a number of deposition, masking, diffusion, etching, and implanting steps. Usually, many individual devices are constructed on the same wafer. When the devices are separated into individual rectangular units, each takes the form of an IC die. In order to interface a die with other circuitry, it is common to mount it on a leadframe or on a multi-chip module substrate that is surrounded by a number of lead fingers. Each die has bonding pads that are then individually connected in a wire-bonding operation to the leadframe's lead fingers using extremely fine gold or aluminum wires. The assemblies are then packaged by individually encapsulating them in molded plastic or ceramic bodies.

IC packaging technology has shown an increase in semiconductor chip density (the number of chips mounted on a single circuit board or substrate) that parallels the reduction in the number of components that are needed for a circuit. This results in packaging designs that are more compact, in form factors (the physical size and shape of a device) that are more compact, and in a significant increase in overall IC density. However, IC density continues to be limited by the space (or “real estate”) available for mounting individual dies on a substrate.

To further condense the packaging of individual devices, multi-chip packages have been developed in which more than one device (such as an IC die) can be included in the same package. Of importance to such complicated packaging designs are considerations of input/output lead count, heat dissipation, matching of thermal expansion and contraction between a motherboard and its attached components, costs of manufacturing, ease of integration into an automated manufacturing facility, package reliability, and easy adaptability of the package to additional packaging interfaces such as a printed circuit board (“PCB”).

In some cases, multi-chip devices can be fabricated faster and more cheaply than a corresponding single IC die that incorporates the same features and functions. Some multi-chip modules consist of a PCB substrate onto which a set of separate IC chip components is directly attached. Other multi-chip modules mount and attach multiple dies on a single leadframe. Following assembly, the multi-chip modules are then encapsulated to prevent damage or contamination. Many such multi-chip modules have greatly increased circuit density and miniaturization, improved signal propagation speed, reduced overall device size and weight, improved performance, and lowered costs—all primary goals of the computer industry.

However, such multi-chip modules can be bulky. IC package density is determined by the area required to mount a die or module on a circuit board. One method to reduce the board size of multi-chip modules is to stack the dies or chips vertically within the module or package. This increases their effective density.

Two of the common die stacking methods are: (a) larger lower die combined with a smaller upper die, and (b) so-called same-size die stacking. With the former, the dies can be very close vertically since the electrical bond pads on the perimeter of the lower die extend beyond the edges of the smaller die on top. With same-size die stacking, the upper and lower dies are spaced more vertically apart to provide sufficient clearance for the wire bonds of the lower die. Then, once the dies are mounted, gold or aluminum bond wires are attached to connect the wire bonding pads on the upper die and on the lower die with the ends of their associated leadframe lead extensions.

Other designs for mounting multiple semiconductor IC chips in a single, multi-chip package have included: a pair of IC dies mounted on opposite sides of a leadframe paddle, two chips mounted on two leadframe paddles, one chip mounted over a paddle and one below mounted on a board, an oblong chip that is rotated and attached on top of another oblong chip attached to a paddle below, one chip attached offset on top of another chip that is attached to a paddle below, one chip attached over another chip by separate spacers between it and the paddle, and various combinations thereof. Such configurations have also been extended to include three or more chips mounted together vertically in a single package.

Unfortunately, such practices for stacked and overlapping dies cause significant limitations for the wire bonding. These stacking arrangements typically entail attaching the upper die onto or immediately above the active surface of the lower die. Such stacking configurations cover or block some or all of the lateral edges of the bonding pads on the lower die. The mounted upper die thus interrupts the wire bond routing for the lower die. As a result, such upper and lower semiconductor dies cannot wire bond.

Thus, despite the advantages of recent developments in semiconductor fabrication and packaging techniques, there is a continuing need for improved packaging designs, systems, and methods to enable increased semiconductor die density in multi-chip packages. A need particularly still remains for such improved stacked die structures in which all the active die pads can also be electrically interconnected to the lead fingers. In view of the need to increase package efficiency and capacity and to reduce package thicknesses, it is increasingly critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides a stacked die packaging system. A substrate and a first die are provided. The first die is attached to the substrate. A film spacer is provided and placed on the first die. A second die is provided and placed on the film spacer. The substrate, the first die, the film spacer, and the second die are encapsulated in an encapsulant.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 is a cross sectional view of a stacked die packaging system according to an embodiment of the present invention;

FIG. 2 is a cross sectional view of the stacked die packaging system in an early stage of manufacture;

FIG. 3 is a cross sectional view of the stacked die packaging system after placement of a film spacer;

FIG. 4 is a cross sectional view of the stacked die packaging system after placement of a second die;

FIG. 5 is a cross sectional view of the stacked die packaging system after the addition of wires to electrically connect the second die;

FIG. 6 is a cross sectional view of the stacked die packaging system after encapsulation in an encapsulant; and

FIG. 7 is a flow chart of a stacked die packaging system in accordance with an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that process or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

The drawings showing embodiments of the system are semi-diagrammatic and not to scale and, particularly, some of the dimensions are for the clarity of presentation and are shown exaggerated in the drawing FIGS. Also, where multiple embodiments are disclosed and described having some features in common, for clarity and ease of illustration, description, and comprehension thereof, like features one to another will ordinarily be described with like reference numerals.

The term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

The term “processing” as used herein includes deposition of material or photoresist, patterning, exposure, development, etching, cleaning, and/or removal of the material or photoresist as required in forming a described structure.

The present invention is directed to stacked die packaging and package fabrication methods for stacked dies that are mounted on a substrate. With existing single-die contemporary designs, all the active pads on the semiconductor die are simultaneously interconnected electrically to the substrate. For a stacked die packaging system, therefore, it is particularly important to support and position the stacked die configuration so that all the semiconductor die bonding pads on both dies are accessible and can be connected simultaneously.

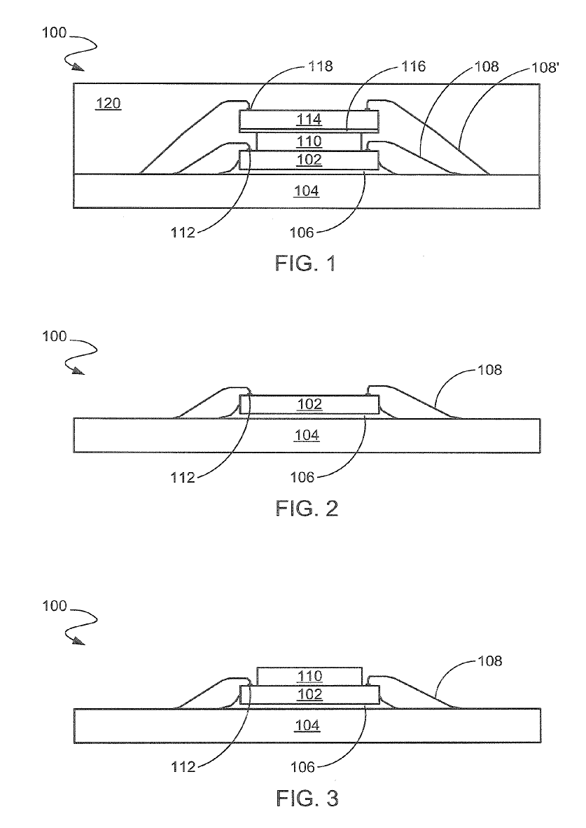

Referring now to FIG. 1, therein is shown a cross sectional view of a stacked die packaging system 100 according to the present invention. The stacked die packaging system 100 includes a first die 102 attached to a substrate 104. The first die 102 is attached with a die attach adhesive 106 or a backside laminated adhesive dielectric film as will be subsequently disclosed.

A film spacer 110 is within the periphery of first die wire bond pads 112. A second die 114 with a backside laminated adhesive dielectric film 116 is on top of the film spacer 110. Wires 108 and 108′ electrically connect the first die 102 and the second die 114 respectively to the substrate 104 at the first die wire bond pads 112 and second die wire bond pads 118.

An encapsulant 120 encapsulates the first die 102, the substrate 104, the adhesive 106, the wires 108, the film spacer 110, the first die wire bond pads 112, the second die 114, the dielectric film 116, and the second die wire bond pads 118.

Referring now to FIG. 2, therein is shown a cross sectional view of the stacked die packaging system 100 in an early stage of manufacture. The first die 102 has been attached to the substrate 104 with the adhesive 106. The wires 108 electrically connect the first die 102 to the substrate 104 at the first die wire bond pads 112.

Referring now to FIG. 3, therein is shown a cross sectional view of the stacked die packaging system 100 after further processing. The film spacer 110 is placed on the first die 102. The film spacer 110 has been precut to a predetermined width, length, and thickness. The width and length of the film spacer 110 were determined such that the film spacer 110 fits within the periphery of the first die wire bond pads 112. The thickness of the film spacer 110 is determined to be greater than the than the loop height of the wires 108. The loop height is defined as the height to the top-most point of a bonded wire from the die to which the wire is bonded. The thickness of the film spacer 110 prevents contact between the wires 108 and the dielectric film 116. Wire bonding may take place before or after placement of the film spacer 110.

The film spacer 110 is made of polymeric components, which are composed of one or more layers. Each layer contains organic or inorganic constituents as fillers. It has been discovered that the film spacer 110 provides improved workability and package reliability.

During the manufacturing process after the first die 102 is attached, the film spacer 110 can be cut to size and then picked up by pick-and-place equipment to be positioned in the proper position on the first die 102.

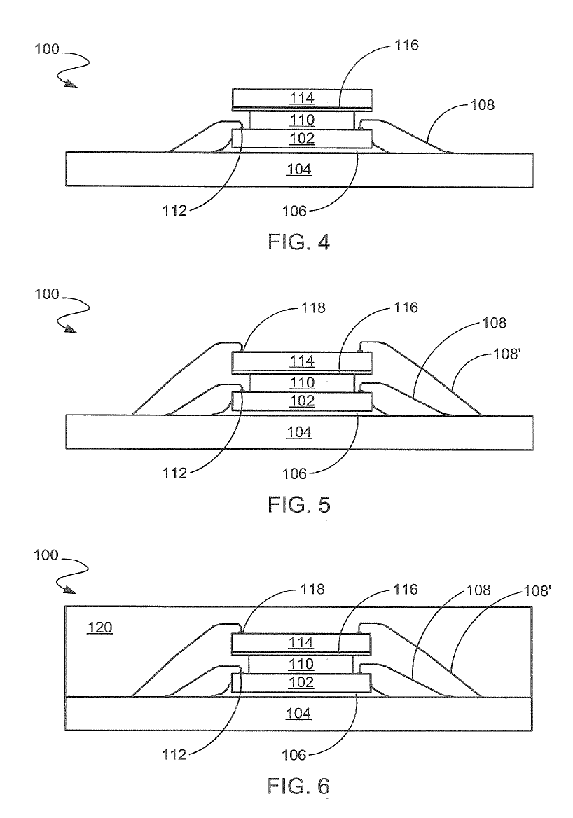

Referring now to FIG. 4, therein is shown a cross sectional view of the stacked die packaging system 100 after further processing. A wafer containing the second die 114 is subject to back grinding, placed with the back, or bottom, of the wafer on the dielectric film 116, and then singulated. This results in the dielectric film 116 covering the entire bottom of the second die 114. The second die 114 with the dielectric film 116 is placed on top of the film spacer 110 and adhered thereto.

It has been discovered that the compliant nature of the polymeric components allows the film spacer 110 to act as a stress reducer between the first die 102 and the second die 114. In addition, the film spacer 110 is electrically non-conductive so it augments the insulative properties of the dielectric film 116 to provide improved insulation between the first die 102 and the second die 114.

Referring now to FIG. 5, therein is shown a cross sectional view of the stacked die packaging system 100 after further processing. Additional wires 108′ have been wire bonded to and electrically connect the substrate 104 and the second die wire bond pads 118 on the second die 114.

Referring now to FIG. 6, therein is shown a cross sectional view of the stacked die packaging system 100 after further processing. The encapsulant 120 encapsulates the first die 102, the substrate 104, the adhesive 106, the wires 108, the film spacer 110, the first die wire bond pads 112, the second die 114, the dielectric film 116, and the second die wire bond pads 118.

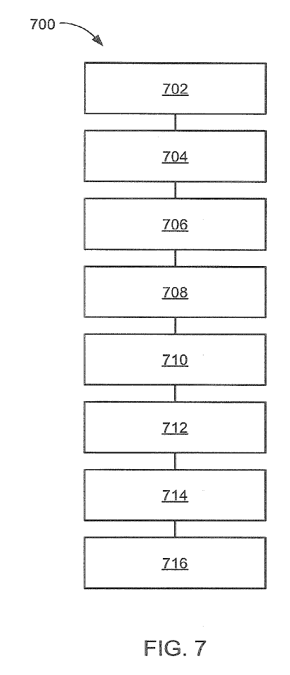

Referring now to FIG. 7, therein is shown a flow chart of a stacked die packaging system 700 in accordance with an embodiment of the present invention. The stacked die packaging system 700 includes providing a substrate in a block 702; providing a first die in a block 704; attaching the first die to the substrate in a block 706; providing a film spacer in a block 708; placing the film spacer on the first die in a block 710; providing a second die in a block 712; placing the second die on the film spacer in a block 714; and encapsulating the substrate, the first die, the film spacer, and the second die in an encapsulant in a block 716.

The invention thus provides a useful system for increasing package efficiency and capacity, and hence reducing the package thickness. As described, the invention provides the stacked semiconductor die system that includes the first semiconductor die that is attached on the substrate and electrically interconnected to the leadframe through bonding wires. The second semiconductor die is attached on the film spacer, which has been previously fabricated, to allow the second semiconductor die to sit firmly and steadily thereon. Bonding pads on the second semiconductor die are then electrically interconnected to the leadframe by bonding wires. The package is then encapsulated with the encapsulant.

In greater detail, a stacked die packaging system, according to an embodiment of the present invention, is thus performed as follows:
(1) The first die 102 is attached to the substrate 104 with the adhesive 106. The wires 108 electrically connect the first die 102 to the substrate 104 at the first die wire bond pads 112. (FIG. 2)
(2) The film spacer 110 is placed on the first die 102 within the periphery of the first die wire bond pads 112. (FIG. 3)
(3) A wafer containing the second die 114 is prepared by back grinding and then the wafer backside laminated with an adhesive dielectric film. The second die 114 with the dielectric film 116 is singulated and placed on top of the film spacer 110. (FIG. 4)
(4) The wires 108 electrically connect the second die 114 to the substrate 104 at the second die wire bond pads 118. (FIG. 5)
(5) The encapsulant 120 encapsulates the first die 102, the substrate 104, the adhesive 106, the wires 108, the film spacer 110, the first die wire bond pads 112, the second die 114, the dielectric film 116, and the second die wire bond pads 118. (FIG. 6)

It has been discovered that the present invention thus has numerous advantages. For example, it enables and supports high package capacity, efficiency, and performance.

Another advantage is that it enables full die pad wire bonding while reducing package thickness.

An additional advantage is that it affords high levels of integration and package density.

A still further advantage is that the present invention facilitates enhancing the circuit capabilities by incorporating multiple dies that can thus support multiple functions in a single package, while reducing the package volume.

Another advantage is that the invention is uncomplicated and thus amenable to lower-cost, rapid volume fabrication and manufacturing.

Yet another advantage of the present invention is that its lower-cost, rapid volume fabrication and manufacturing valuably support and service the historical trend of reducing costs, simplifying systems, and increasing performance.

These and other valuable aspects of the present invention consequently further the state of the technology to at least the next level.

Thus, it has been discovered that the stacked die packaging system of the present invention furnishes important and heretofore unknown and unavailable solutions, capabilities, and functional advantages for increasing package efficiency and capacity and reducing package thicknesses. The resulting processes and configurations are straightforward, cost-effective, uncomplicated, highly versatile, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations which fall within the scope of the included claims. All matters hithertofore set forth herein or shown in the accompanying drawings are to be interpreted in an illustrative and non-limiting sense.

1. A stacked die packaging system, comprising:
providing a substrate;
providing a first die;
attaching the first die to the substrate;
providing a film spacer;
placing the film spacer on the first die;
providing a second die;
attaching the second die with a backside laminated adhesive dielectric film on the film spacer; and
encapsulating the substrate, the first die, the film spacer, and the second die in an encapsulant.

2. The system as claimed in claim 1 wherein;
providing a first die further comprises providing a first die that has wire bond pads; and
placing the film spacer on the first die further comprises placing the film spacer within the periphery of the wire bond pads.

3. The system as claimed in claim 1 further comprising:
electrically connecting the first die to the substrate with wires; and
providing the film spacer on the first die further comprises providing a film spacer that is thicker than the loop height of the wires.

4. (canceled)

5. The system as claimed in claim 1 wherein providing the film spacer provides a film made of at least one layer of polymeric components.

6. A stacked die packaging system, comprising:
providing a substrate;
attaching a first die with a first backside laminated adhesive dielectric film to the substrate;
electrically connecting the first die to the substrate with wires at first die wire bond pads;
placing a film spacer on the first die;
placing a second die with a second backside laminated adhesive dielectric film on the film spacer;
electrically connecting the second die to the subsrate with the wires at second die wire bond pads; and
encapsulating the substrate, the first die, the backside laminated adhesive film, the wires, the film spacer, and the second die in an encapsulant.

7. The system as claimed in claim 6 wherein placing the film spacer on the first die further comprises placing the film spacer within the periphery of the first die wire bond pads.

8. The system as claimed in claim 6 wherein placing the film spacer on the first die further comprises placing the film spacer having a thickness greater than the loop height of the wires connected to the first die wire bond pads.

9. The system as claimed in claim 6 further comprising:
attaching the second die to the film spacer by the backside laminated adhesive dielectric film.

10. The system as claimed in claim 6 wherein providing the film spacer provides a film made of at least one layer of polymeric components containing organic or inorganic constituents as fillers.

11. A stacked die packaging system, comprising:
a substrate;
a first die on the substrate;
a film spacer on the first die;
a second die with a backside laminated adhesive dielectric film on the film spacer; and
an encapsulant encapsulating the substrate, the first die, the film spacer, and the second die.

12. The system as claimed in claim 11:
further comprising wire bond pads; and
wherein the film spacer is within the periphery of the wire bond pads.

13. The system as claimed in claim 11:
further comprising wires that electrically connect the first die to the substrate; and
wherein the film spacer is slightly higher than the wires.

14. (canceled)

15. The system as claimed in claim 11 wherein the film spacer is a film made of at least one layer of polymeric components.

16. The system as claimed in claim 11 further comprising:
first die wire bond pads;
second die wire bond pads;
wires electrically connecting the first die and the second die to the substrate at the first die wire bond pads and the second die wire bond pads; and
the encapsulant encapsulating the wires; and
the first die with a second backside laminated adhesive dielectric film attached to the substrate.

17. The system as claimed in claim 16 wherein the film spacer is within the periphery of the first die wire bond pads.

18. The system as claimed in claim 16 wherein the film spacer has a height similar to or slightly higher than the loop height of the wires.

19. (canceled)

20. The system as claimed in claim 16 wherein the film spacer is a film made of at least one layer of polymeric components containing organic or inorganic constituents as fillers.
